(19) United States
(12) Patent Application Publication
(10) Pub. No.: US 2024/0168057 A1
(43) Pub. Date: May 23, 2024

(54) PROBE CARD FOR HIGH-FREQUENCY TESTING

(71) Applicant: STAR TECHNOLOGIES, INC., Hsinchu City (TW)

(72) Inventors: HUNG-CHUN HUANG, HSINCHU CITY (TW); WEN-HAO CHENG, ZHUBEI CITY (TW); YUAN-TING TAI, HSINCHU COUNTY (TW)

(21) Appl. No.: 18/132,481

(22) Filed: Apr. 10, 2023

(30) Foreign Application Priority Data
Nov. 18, 2022 (TW) 111144094

(51) Int. Cl. G01R 1/067; G01R 1/073

(52) U.S. Cl. CPC G01R 1/06772; G01R 1/07342

(57) ABSTRACT

A probe card for high-frequency testing is provided. The probe card includes a substrate, a flexible substrate, a probe, and at least one movable conductive pillar. The substrate has a first surface, a second surface, and at least one first through hole. The flexible substrate is disposed on the second surface of the substrate and has at least one second through hole. The second through hole and the first through hole correspond to each other. The probe is disposed on the second surface of the substrate, and is electrically connected to the flexible substrate. The movable conductive pillar movably passes through the first through hole and the second through hole.

### FIELD OF THE DISCLOSURE

The present disclosure relates to a probe card structure, and more particularly to a probe card structure high-frequency testing, which includes a movable conductive pillar so as to enable a flexible substrate and a substrate to be conductive.

### BACKGROUND OF THE DISCLOSURE

A method of testing an integrated circuit component on a wafer is to allow a plurality of probes on a probe card to be in contact with a testing pad, transmit the testing signal, receive the measurement signals, and finally analyze the output signal to determine a quality of the integrated circuit component. With the development of high-frequency and high-density integrated circuit components, the probe not only needs to be arranged more densely, but also a probe card must has a suitable design for interference isolation, so that during operation under the high-speed clock, the probe can be avoided from severe signal interference. In the conventional technology, a length of the probe is reduced in response to the requirement of high-frequency testing, and the probe is connected to a coaxial cable or a flexible substrate for transmitting high-frequency signals, thereby reducing the environmental interference of the high-frequency signal. However, in a cantilever probe card (CPC) structure, the signal from the probe needs to be transmitted from a probe side to a tester side, so that the signal can be returned to the tester for analysis.

Referring to FIG. 9 and FIG. 10, a structure of a probe card in the prior art is shown. As shown in FIG. 9, one example of a probe card 200a of the prior art includes a substrate 10X, a probe 30X, a holding part 50X, and a coaxial cable 60X. The substrate 10X has a first surface 101 (also referred to a tester side), a second surface 102 (also referred to a probe side), and a through hole C. The coaxial cable 60X passes through the through hole C, such that the signal can be transmitted from the probe side to the tester side, and then the coaxial cable 60X directly transmits the signal from the tester side to a conductive trace 70X of the substrate 10X. Referring to FIG. 10, in another example of a probe card 200b of the prior art, by having the coaxial cable 60X been correspondingly and electrically connected to a flexible substrate 20X and a probes 30X, and having the conductive trace 70X been electrically connected to flexible substrate 20X, the signal can be transmitted from the probe side to the tester side. Referring to FIG. 11, in still another example of a probe card 200c of the prior art, the probe 30X on the probe side is electrically connected to the conductive trace 70X on the tester side through the coaxial cable 60X.

However, in the probe card 200a in the prior art shown in FIG. 9, the coaxial cable 60X needs to be extended from the probe side to the tester side, resulting in increased cost and time consumption. In the probe card 200b in the prior art shown in FIG. 10, if the conductive trace 70X arranged in the substrate 10X is broken, it cannot be repaired and the probe card 200b needs to be wholly replaced, resulting in increased cost. In the probe card 200c in the prior art shown in FIG. 11, the coaxial cable 60X needs to be extended from the probe side to the tester side, resulting in increased cost and time consumption.

Therefore, in the prior art, there are disadvantages such as increment cost, long manufacturing time, and inability to repair the conductive trace when it is broken, which are needed to be solved by skilled in the art.

### SUMMARY OF THE DISCLOSURE

In response to the above-referenced technical inadequacies, the present disclosure provides a probe card for high frequency testing, which comprises a substrate, a probe, at least one movable conductive pillar, and a signal path. The substrate has a first surface, a second surface and at least one first through hole, and the first through hole is connected to the first surface and the second surface. The probe is disposed on the second surface of the substrate. The at least one movable conductive pillar can be movably passed through a corresponding one of the first through hole. The signal path is disposed on the second surface of the substrate, so that the probe is electrically connected to the movable conductive pillar.

In certain embodiments, the signal path includes a flexible substrate, the flexible substrate is disposed on the second surface of the substrate and has at least one second through hole, and the second through hole corresponds to the first through hole, so that at least one movable conductive pillar can be movably passed through the corresponding one of the first through hole and a corresponding one of the second through hole.

In certain embodiments, the signal path further includes a coaxial cable, the coaxial cable is disposed on the second surface of the substrate and is electrically connected between the probe and the flexible substrate.

In certain embodiments, the signal path is the coaxial cable, the coaxial cable is disposed on the second surface of the substrate, and is electrically connected between the probe and the movable conductive pillar.

In certain embodiments, the probe card for high frequency testing includes a conductive trace, the conductive trace is disposed on the first surface of substrate, and the at least one movable conductive pillar is electrically connected to the conductive trace.

In certain embodiments, the movable conductive pillar is inserted into the second through hole in a direction from the flexible substrate toward the substrate, a first part is passes through the first through hole, and a second part passes through the second through hole.

In certain embodiments, the movable conductive pillar includes a grounded conductive pillar and a signal transduction conductive pillar, and the grounded conductive pillar and the signal transduction conductive pillar are respectively disposed in different first through holes.

In certain embodiments, the movable conductive pillar includes a signal transduction layer and a grounded layer, and the grounded layer is disposed around the signal transduction layer or the signal transduction layer is disposed around the grounded layer.

In certain embodiments, the movable conductive pillar is inserted into the first through hole in a direction from the substrate toward the flexible substrate.

In certain embodiments, a cross sectional area of the first through hole is less than a cross sectional area of the second through hole, the movable conductive pillar has a first part and a second part, and a cross sectional area of the first part is less than a cross sectional area of the second part.

In certain embodiments, the cross sectional area of the first through hole is greater than the cross sectional area of the second through hole, the movable conductive pillar has the first part and the second part, and the cross sectional area of the first part is greater than the cross sectional area of the second part.

In certain embodiments, a shape of the first through hole is different from a shape of the second through hole, the movable conductive pillar has the first part and the second part, a shape of the first part is the same as the shape of the first through hole, a shape of the second part is the same as the shape of the second through hole, the movable conductive pillar is inserted into the second through hole in the direction from the flexible substrate toward the substrate or the movable conductive pillar is inserted into the first through hole from the substrate in the direction toward the flexible substrate.

In certain embodiments, a length of the first part is greater than or equal to a depth of the first through hole, and a length of the second part is equal to a depth of the second through hole.

In certain embodiments, the probe card for high frequency testing includes a coaxial cable, one end of the coaxial cable is electrically connected to the probe, and another end of the coaxial cable is electrically connected to the flexible substrate.

In certain embodiments, the substrate further includes a groove, and the flexible substrate is accommodated in the groove.

One of the beneficial effects of the present disclosure is that, in the probe card for high frequency testing provided by the present disclosure, the signal from the probe can be transmitted from the second surface of the substrate to the first surface of the substrate through the movable conductive pillar. The adoption of the conductive pillar can simplify a wiring design in the probe card, so that a broken of the conductive trace can be accordingly reduced. In addition, the substrate is tested to determine whether there is a short circuit in the conductive trace when feeding. Therefore, the adoption of the conductive pillar in the present disclosure simplifies the wiring design, so that the broken of the conductive trace can be further reduced, thereby effectively shortening the testing time. Further, the cost and manufacturing time can be reduced.

On the other hand, more layout layers (especially for the high-frequency testing) disposed on the substrate results in higher costs. Therefore, the use of conductive pillar can lower the layout cost.

When the movable conductive pillar is unusable, the probe can be reused only by replacing the movable conductive pillar. In addition, the movable conductive pillars has the first part and the second part respectively arranged in the first through hole and the second through hole. With the difference in cross-sectional area and shape of the first part and the second part, a limiting function can be achieved, and a setting direction of the movable conductive pillar can be effectively ensured.

In order to further understand the features and technical content of the present disclosure, please refer to the following detailed description and drawings of the present disclosure. However, the drawings provided are only for reference and description, and are not intended to limit the present disclosure.

### BRIEF DESCRIPTION OF THE DRAWINGS

The described embodiments may be better understood by reference to the following description and the accompanying drawings, in which:

FIG. 1 is a schematic view of a probe card for high-frequency testing according to a first embodiment of the present disclosure;

FIG. 2 is a schematic enlarged view of part II of FIG. 1;

FIG. 3 is a schematic view of a movable conductive pillar of the probe card for high-frequency testing according to the first embodiment of the present disclosure;

FIG. 4 is a schematic view of one example of the movable conductive pillar according to the first embodiment of the present disclosure;

FIG. 5 is a schematic view of another example of the movable conductive pillar according to the first embodiment of the present disclosure;

FIG. 6 is a schematic view of still another example of the movable conductive pillar according to the first embodiment of the present disclosure;

FIG. 7 is a schematic view of yet another example of the movable conductive pillar according to the first embodiment of the present disclosure;

FIG. 8 is a schematic view of a probe card for high-frequency testing according to a second embodiment of the present disclosure;

FIG. 9 is a schematic view of one example of a probe card of the prior art;

FIG. 10 is a schematic view of another example of the probe card of the prior art; and

FIG. 11 is a schematic view of still another example of the probe card of the prior art.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

### First Embodiment

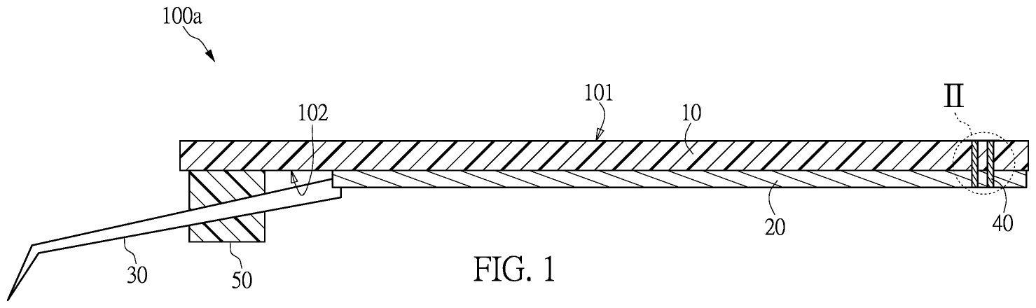

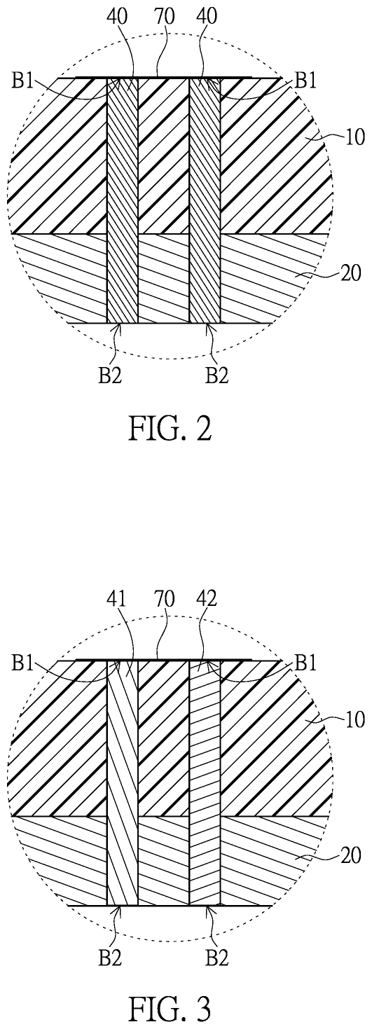

Referring to FIG. 1, a first embodiment of the present disclosure provides a probe card for high frequency testing 100a, which includes a substrate 10, a flexible substrate 20, a probe 30, a holding part 50, and at least one movable conductive pillar 40. As shown in FIG. 2, the substrate 10 has a first surface 101, a second surface 102, and at least one first through hole B1. In some embodiments, the substrate 10 can be a circuit board. The first through hole B1 is correspondingly connected to the first surface 101 and the second surface 102. The first surface 101 and the second surface 102 can be parallel to each other. A quantity of the first through hole B1 can be adjusted according to the practical requirements. The quantity of the first through holes B1 shown in the figures is two as an example.

A signal path is disposed on the second surface 102 of the substrate 10, so that the probe 30 and the movable conductive pillar are electrically connected, and the signal path can be a coaxial cable or the flexible substrate 20.

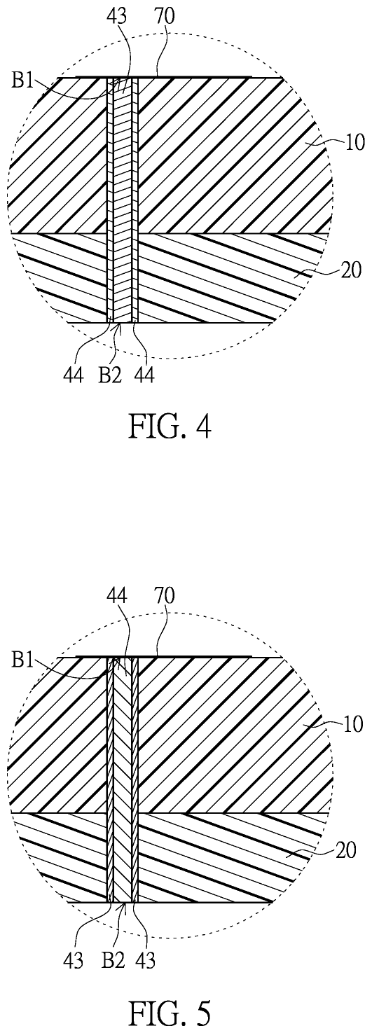

The flexible substrate 20 is disposed on the second surface 102 of the substrate 10 and has at least one second through hole B2. As shown in FIG. 2, the second through hole B2 is arranged corresponding to the first through hole B1. A quantity of the second through hole B2 is the same as the number of the first through hole B1. For example, the quantity of the second through hole B2 shown in FIG. 2 and FIG. 3 is exemplarily two, and the quantity of the second through hole B2 shown in FIG. 4 and FIG. 5 is exemplarily one. The probe 30 is disposed on the second surface 102 of the substrate 10, and is fixed by the holding part 50 on the second surface 102. Furthermore, the probe 30 is electrically connected to the flexible substrate 20.

Referring to FIG. 2, the movable conductive pillar 40 can be electrically connected to the flexible substrate 20, and can movably pass through a corresponding one of the first through hole B1 and a corresponding one of the second through hole B2. An impedance of the movable conductive pillar 40 and an impedance of the flexible substrate 20 can be the same, so that an electrical property is not affected. However, the present disclosure is not limited thereto. One end of the movable conductive pillar 40 is parallel to the first surface 101 of the substrate 10, and another end of the movable conductive pillar 40 is parallel to the second surface 102 of the substrate 10.

When the movable conductive pillar 40 correspondingly passes through the first through hole B1 and the second through hole B2, the movable conductive pillar 40 can be fixed on the first surface 101 or the second surface 102 of the substrate 10 by soldering. A material of the movable conductive pillar 40 can be copper, but the present disclosure does not limit the material of the movable conductive pillar 40. The movable conductive pillar 40 can be fixed on the substrate 10 through, for example, mechanical interference, a solder, a conductive trace 70, an adhesive, a conductive glue, etc., so that the signal transmitted from the probe 30 can pass through the flexible substrate 20, the movable conductive pillar 40 transmits the signal from the second surface 102 of the substrate 10 to the first surface 101 of the substrate 10, and then transmits the signal to the testing machine (not shown). In the diagram of this embodiment, the number of movable conductive pillar 40 is the same as the number of the first through hole B1 and the second through hole B2.

Referring to FIG. 3, in one particular embodiment, the movable conductive pillar 40 can include a grounded conductive pillar 41 and a signal transduction conductive pillar 42. The grounded conductive pillar 41 and the signal transduction conductive pillar 42 respectively pass through different through holes. The grounded conductive pillar 41 is used for grounding and the signal transduction conductive pillar 42 is used for transmitting the signal from the probe 30.

Referring to FIG. 4 and FIG. 5, in one particular embodiment, one movable conductive pillar 40 may include a signal transduction layer 44 and a ground layer 43. As shown in FIG. 4, the signal transduction layer 44 of the movable conductive pillar 40 is disposed around the ground layer 43. As shown in FIG. 5, the ground layer 43 of the movable conductive pillar 40 is disposed around the signal transduction layer 44.

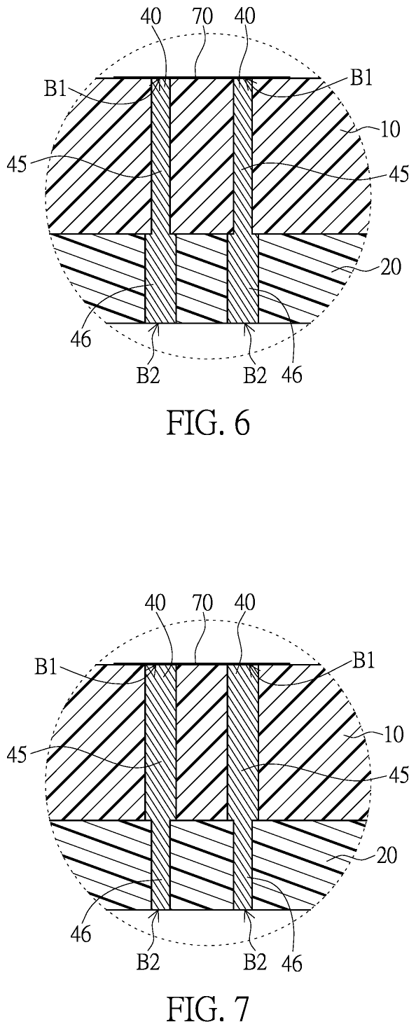

Referring to FIG. 6 and FIG. 7, the movable conductive pillar 40 has a first part 45 and a second part 46. A length of the first part 45 is greater than or equal to a depth of the first through hole B1, and a length of the second part 46 is greater than or equal to a depth of the second through hole B2.

As shown in FIG. 6, a cross sectional area of the first through hole B1 is less than a cross sectional area of the second through hole B2, and a cross sectional area of the first part 45 is less than a cross sectional area of the second part 46. Therefore, when the movable conductive pillar 40 passes through the substrate 10, the movable conductive pillar 40 sequentially passes through the second through hole B2 and the first through hole B1 in a direction from the flexible substrate 20 toward the substrate 10.

As shown in FIG. 7, the cross sectional area of the first through hole B1 is greater than the cross sectional area of the second through hole B2, the cross sectional area of the first part 45 is greater than the cross sectional area of the second part 46, and the movable conductive pillar 40 sequentially passes the first through hole B1 and the second through hole B2 in a direction toward the flexible substrate 20. The designs shown in FIG. 6 and FIG. 7 can achieve a limiting effect and can effectively ensure that the movable conductive pillar 40 is stably fixed in the first through hole B1 and the second through hole B2.

Furthermore, a shape of the first through hole B1 can be the same as or different from a shape of the second through hole B2. In one particular embodiment, the shape of the first through hole B1 and the shape of the second through hole B2 are different. When the shape of the first through hole B1 and the shape of the second through hole B2 are different, a shape of the first part 45 is the same as the shape of the first through hole B1, and a shape of the second part 46 is the same as the shape of the second through hole B2. Therefore, the movable conductive pillar 40 can sequentially pass through the second through hole B2 and the first through hole B1 in a direction from the flexible substrate 20 toward the substrate 10. Alternately, the movable conductive pillar 40 can sequentially pass through the first through hole B1 and the second through hole B2 in a direction from the substrate 10 toward the flexible substrate 20.

In addition, according to the actual needs, the first through hole B1 and the second through hole B2 of different sizes and shapes can cooperate to effectively ensure that the movable conductive pillar 40 is stably fixed on the first through hole B1 and the second through hole B2.

### Second Embodiment

The present embodiment is similar to the first embodiment, and the similarities therebetween will not be reiterated herein (e.g. the probe 30, the holding part 50, the movable conductive pillar 40, and the conductive trace 70, etc.).

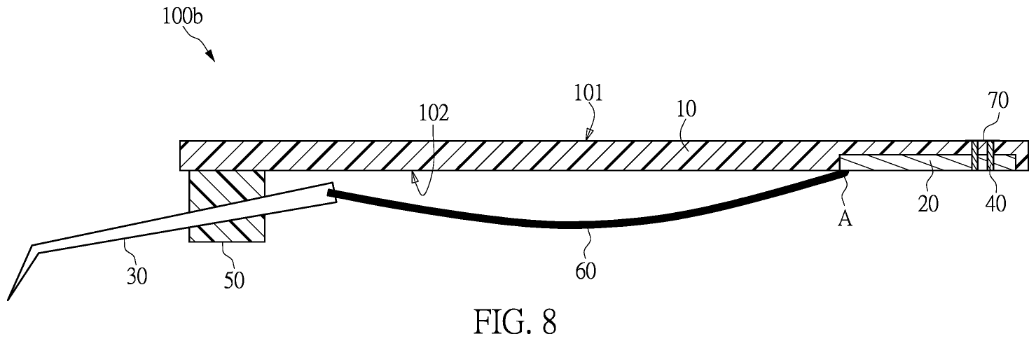

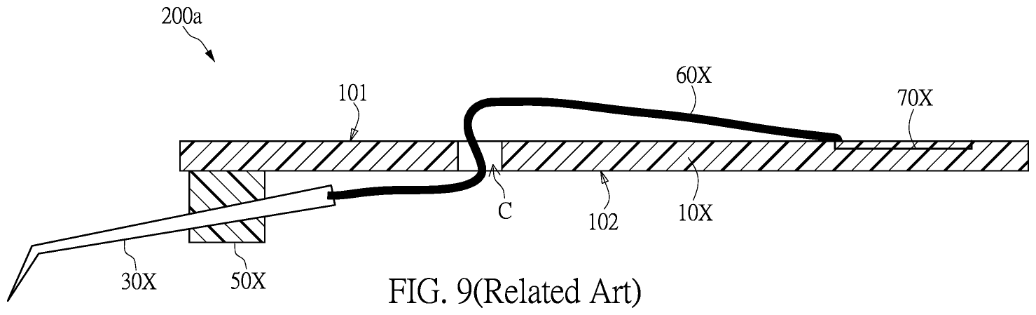

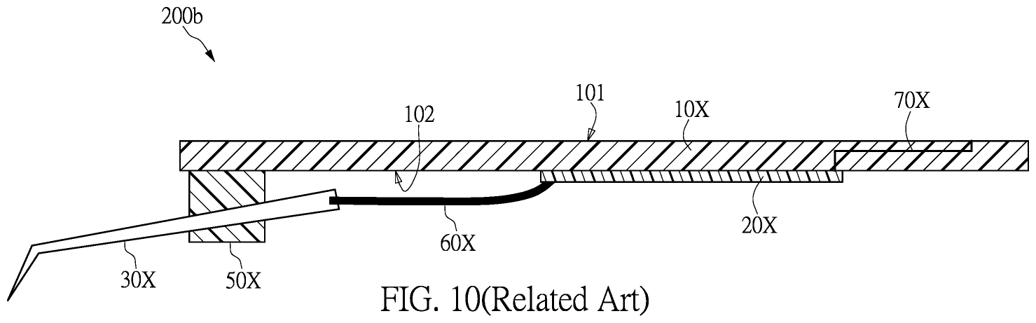

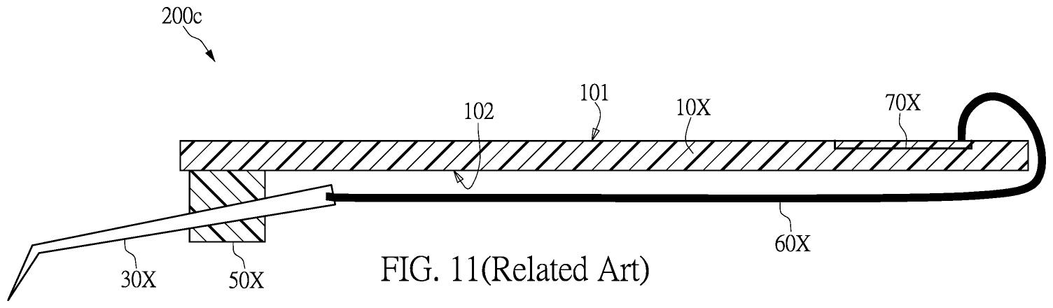

Referring to FIG. 8, the second embodiment of the present disclosure provides a probe card for high-frequency testing 100b, which includes a coaxial cable 60. The second surface 102 of the substrate 10 has a groove A for accommodating the flexible substrate 20. The coaxial cable 60 is disposed on the second surface 102 of the substrate 10, one end of the coaxial cable 60 is electrically connected to the probe 30, and another end of the coaxial cable 60 is electrically connected to the flexible substrate 20. The movable conductive pillar 40 and the flexible substrate 20, the probe 30 and the coaxial cable 60 may a same impedance to ensure that the electrical property is not affected. However, the present disclosure is not limited thereto. In one embodiment, a length of the groove A is greater than a length of the coaxial cable 60 so that a signal interference can be reduced.

In FIG. 8, the length of the coaxial cable 60 and a length of the flexible substrate 20 are not limited. The length of the coaxial cable 60 can be determined according to a path length of each coaxial cable 60, a layout of components on the flexible substrate 20, and a design flexibility. Although it is possible to enable the flexible substrate 20 to have a better anti-interference design in high-frequency signal transmission, the coaxial cable 60 can also be used in general signal transmission. Therefore, in some embodiments, the probe card for high-frequency testing 100b can includes: only the coaxial cable 60 correspondingly connected to the probe 30 and the movable conductive pillar 40, only the flexible substrate 20 correspondingly connected to the probe 30 and the movable conductive pillar 40, or the coaxial cable 60 and the flexible substrate 20 each correspondingly connected to the probe 30 and the movable conductive pillar 40.

### Beneficial Effects of the Embodiments

One of the beneficial effects of the present disclosure is that, in the probe card for high frequency testing provided by the present disclosure, the signal from the probe can be transmitted from the second surface of the substrate to the first surface through the movable conductive pillar. The adoption of the conductive pillar can simplify a wiring design in the probe card, so that a broken of the conductive trace can be accordingly reduced. In addition, the substrate is tested to determine whether there is a short circuit in the conductive trace when feeding. Therefore, the adoption of the conductive pillar in the present disclosure simplifies the wiring design, so that the broken of the conductive trace can be further reduced, thereby effectively shortening the testing time. Further, the cost and manufacturing time can be reduced.

On the other hand, more layout layers (especially for the high-frequency testing) disposed on the substrate results in higher costs. Therefore, the use of conductive pillar can lower the layout cost.

When the movable conductive pillar is unusable, the probe can be reused only by replacing the movable conductive pillar. In addition, the movable conductive pillar has the first part and the second part respectively arranged in the first through hole and the second through hole. With the difference in cross-sectional area and shape of the first part and the second part, a limiting function can be achieved, and a setting direction of the movable conductive pillar can be effectively ensured.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card for high-frequency testing, comprising:
a substrate, the substrate having a first surface, a second surface, and at least one first through hole, the first through hole being correspondingly connected to the first surface and the second surface;
a probe, the probe being disposed on the second surface of the substrate;
at least one movable conductive pillar movably passing through a corresponding one of the first through hole; and
a signal path, wherein the signal path is disposed on the second surface of the substrate, so that the probe is electrically connected to the movable conductive pillar.

2. The probe card according to claim 1, wherein the signal path includes a flexible substrate, the flexible substrate is disposed on the second surface of the substrate and has at least one second through hole, and the second through hole corresponds to the first through hole, so that the at least one movable conductive pillar movably passes through the corresponding one of the first through hole and a corresponding one of the second through hole.

3. The probe card according to claim 2, wherein the signal path further includes a coaxial cable, and the coaxial cable is disposed on the second surface of the substrate, and is electrically connected between the probe and the flexible substrate.

4. The probe card according to claim 1, wherein the signal path further includes a coaxial cable, the coaxial cable is disposed on the second surface of the substrate, and is electrically connected between the probe and the movable conductive pillar.

5. The probe card according to claim 1, further comprising:
a conductive trace, the conductive trace being disposed on the first surface of the substrate, and the at least one movable conductive pillar is electrically connected to the conductive trace.

6. The probe card according to claim 5, wherein a length of a first part is greater than or equal to a depth of the first through hole, and a length of a second part is equal to a depth of the second through hole.

7. The probe card according to claim 5, wherein the movable conductive pillar is inserted into the second through hole from the flexible substrate in a direction toward the substrate, a first part passes through the first through hole, and a second part passes through the second through hole.

8. The probe card according to claim 7, wherein a length of the first part is greater than or equal to a depth of the first through hole, and a length of the second part is equal to a depth of the second through hole.

9. The probe card according to claim 1, wherein the movable conductive pillar includes a grounded conductive pillar and a signal transduction conductive pillar, and the grounded conductive pillar and the signal transduction conductive pillar respectively pass through different first through holes.

10. The probe card according to claim 9, wherein a length of a first part is greater than or equal to a depth of the first through hole, and a length of a second part is equal to a depth of the second through hole.

11. The probe card according to claim 1, wherein the movable conductive pillars include a signal transduction layer and a grounded layer, and the grounded layer surrounds the signal transduction layer or the signal transduction layer surrounds the grounded layer.

12. The probe card according to claim 11, wherein a length of a first part is greater than or equal to a depth of a first through hole, and a length of the second part is equal to a depth of the second through hole.

13. The probe card according to claim 8, wherein the movable conductive pillar is inserted into the first through hole from the flexible substrate in a direction toward the substrate.

14. The probe card according to claim 1, wherein a cross sectional area of the first through hole is less than a cross sectional area of the second through hole, the movable pillars has a first part and a second part, and a cross sectional area of the first part is less than a cross sectional area of the second part.

15. The probe card according to claim 14, wherein a length of a first part is greater than or equal to a depth of the first through hole, and a length of a second part is equal to a depth of the second through hole.

16. The probe card according to claim 1, wherein a cross sectional area of the first through hole is greater than a cross sectional area of the second through hole, the movable conductive pillar has a first part and a second part, and a cross sectional area of the first part is greater than a cross sectional area of the second part.

17. The probe card according to claim 1, wherein a shape of the first through hole is different from a shape of second through hole, the movable conductive pillar has a first part and a second part, a shape of the first part is the same as the shape of the first through hole, a shape of the second part is the same as the shape of the second through hole, the movable conductive pillar is inserted into the second through hole from the substrate in a direction toward a flexible substrate; or the movable conductive pillar is inserted into the first through hole from the substrate in a direction toward a flexible substrate.

18. The probe card according to claim 1, further comprising:
a coaxial cable, wherein one end of the coaxial cable is electrically connected to the probe, and another end of the coaxial cable is electrically connected to a flexible substrate.

19. The probe card according to claim 1, wherein the substrate further includes a groove, and a flexible substrate is accommodated in the groove.
